(19) United States
(12) Patent Application Publication
(10) Pub. No.: US 2010/0046168 A1
(43) Pub. Date: Feb. 25, 2010

(54) Heat dissipating device

(75) Inventor: Been Yu Liaw, Taipei County (TW)

Correspondence Address: Been Yu Liaw, P.O. Box 44-2049, Taipei, 10668, TW

(73) Assignee: Green Lighting, Inc.

(21) Appl. No.: 12/222,977

(22) Filed: Aug. 21, 2008

(51) Int. Cl. H05K 7/20

(52) U.S. Cl. 361/704

(57) ABSTRACT

A heat dissipating device includes a plurality of heat dissipating fins are sequentially connected together to form a continuous and cascaded heat dissipating fin set. The heat dissipating fin set having an outward radial shape. The heat dissipating fins comprise at least one local arc shape. Surfaces of the heat dissipating fins having projections and depressions to enlarge a heat dissipating area. Edges of the fins are formed with curved surface corners to prevent an operator from being cut and hurt.

### BACKGROUND OF THE INVENTION

(1) Field of the Invention

The invention relates to a heat dissipating device, and more particularly to a heat dissipating device having heat dissipating fins. The features of the heat dissipating device includes the high density, the low flow resistance and an operator cannot be easily hurt or cut by it.

(2) Description of the Prior Art

At present, the fins of the heat dissipating device are made by way of aluminum extruding, die casting and folding. Because of the limitation of the mechanical fabricating ability, the density (the total heat dissipating area per unit volume) of the fins which are manufactured by way of aluminum extruding and die casting is easily to be broken. Therefore, the efficiency of the heat dissipating device is improved with the fin-type heat dissipating devices manufactured by way of aluminum extruding and die casting. The density of the fin-type heat dissipating device made by way of folding is higher than the aluminum extruding and die casting types, and thus the fin-type heat dissipating device made by way of aluminum extruding or die casting could to be replaced.

The fins of the conventional fin-type heat dissipating device are made by mechanical pressing a plurality thin-plate-type heat dissipating fins into given sizes. The heat dissipating fin is made of a metal material having the good thermal conductivity, wherein the metal material is copper or aluminum. The fin-type heat dissipating device is attached to a material with the good heat transfer property or to a heat source, such as an electronic heat-emitting element. The fin-type heat dissipating device composed of the heat dissipating fins is configured to assist dissipating the heat of the heat source.

However, the operator is easily to be cut and hurt by the sharp outer edge of the fin-type heat dissipating device made by way of folding. The density (the total heat dissipating area per unit volume) is higher than the aluminum extruding or die casting type, the fin-type heat dissipating device still has to be improved.

The conventional fin-type heat dissipating device still has the inconvenience and drawback in practical usage and has to be improved. Therefore, the present inventor has paid attention to the research and the development according to the experience and the technology in manufacturing the associated products for many years. Therefore, there is a need to provide a heat dissipating device to improve the above-mentioned drawbacks.

### SUMMARY OF THE INVENTION

In order to enhance the heat dissipation efficiency, it is therefore an object of the invention to provide a heat dissipating device for dissipating heat generated by an electronic element. The heat dissipating device is formed by combining a plurality of fins. The fins at least include local arc and curved surfaces. To prevent an operator from being cut and hurt the edges of the fins are formed with curved surface corners which can significantly enlarge a heat dissipating area so that the heat dissipation efficiency can be enhanced.

Another aspect of the invention is to provide fins having concave-convex patterns on the surfaces so that the heat dissipating area can be enlarged and the heat dissipation efficiency can be enhanced.

Another aspect of the invention is to provide fins having one hole or a plurality of holes according to the requirement so that the heat dissipating effect can be enhanced.

To achieve the above-mentioned objects the invention provides a heat dissipating device mainly including a plurality of heat dissipating fins sequentially connected together to form a continuous cascaded heat dissipating fin set. The heat dissipating fin set having an outward radial shape and local arc shapes. The surfaces of the fins comprise projections and depressions to increase the heat dissipating area. To prevent an operator from being cut and hurt the edges of the fins are formed with curved surface corners. The heat dissipating device may also work in conjunction with a heat dissipating fan to increase the heat dissipation efficiency.

The foregoing and other objectives, features, and advantages of the invention will be apparent from the following, more particular, description of the preferred embodiment of the invention, as illustrated in the accompanying drawings.

### BRIEF DESCRIPTION OF THE DRAWINGS

FIG. 1 is a pictorial view showing a heat dissipating device of the invention;

FIG. 2 is a schematic view illustrates a fin of the heat dissipating device of the invention;

FIG. 3 is a schematic view illustrates a fin of the heat dissipating device according to another embodiment of the invention;

FIG. 4 is a side view illustrates the heat dissipating fin of the invention; and

FIG. 5 illustrates an application embodiment of the heat dissipating device according to the invention.

### DETAILED DESCRIPTION OF THE PREFERRED EMBODIMENTS

The characteristic contents, advantages and achieved effects of the present invention will become more fully understood from the detailed description given herein below and the accompanying drawings which are given by way of illustration only, and thus are not limitative of the present invention.

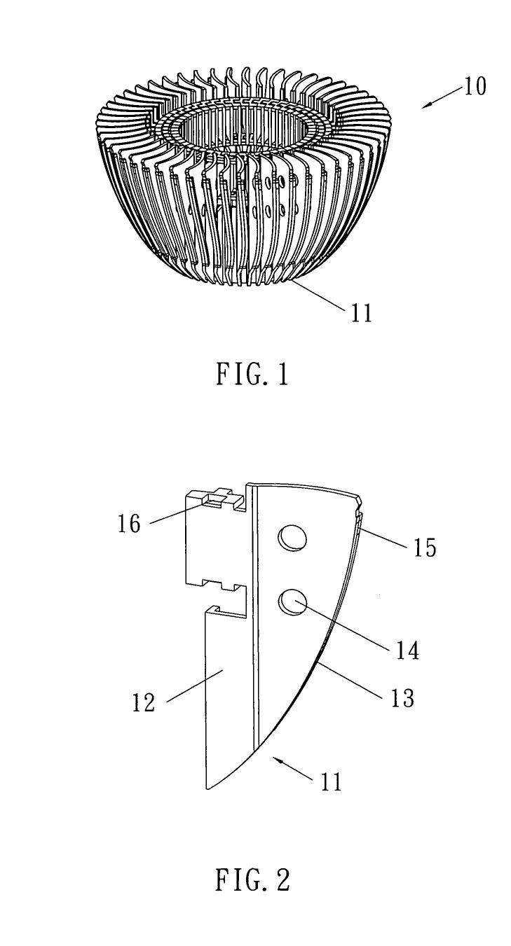

FIG. 1 is a pictorial view showing a heat dissipating device of the invention. Refer to FIG. 1 the heat dissipating device 10 including a plurality of heat dissipating fins 11 are sequentially connected together to form a continuous and cascaded heat dissipating fin set, wherein the size of the heat dissipating device can be arbitrarily changed, the heat dissipating fin set is an outward radial shape. The heat dissipating fins 11 includes at least one local arc shape, and edges of the fins are formed with curved surface corners to prevent an operator from being cut and hurt. The heat dissipating device 10 may also work in conjunction with a heat dissipating fan (not show) to improve the efficiency of the heat dissipation.

FIG. 2 is a schematic view illustrates a heat dissipating fin 11 of the heat dissipating device of the invention. As shown in FIG. 2, the heat dissipating fin 11 has an inner plate edge 12 and an outer plate edge 13. The inner plate edge 12 includes a connection member 16, and the outer plate edge 13 includes a curved surface corner 15. The heat dissipating fin 11 has one hole or a plurality of holes 14 to increase the thermal convection and the heat dissipating area.

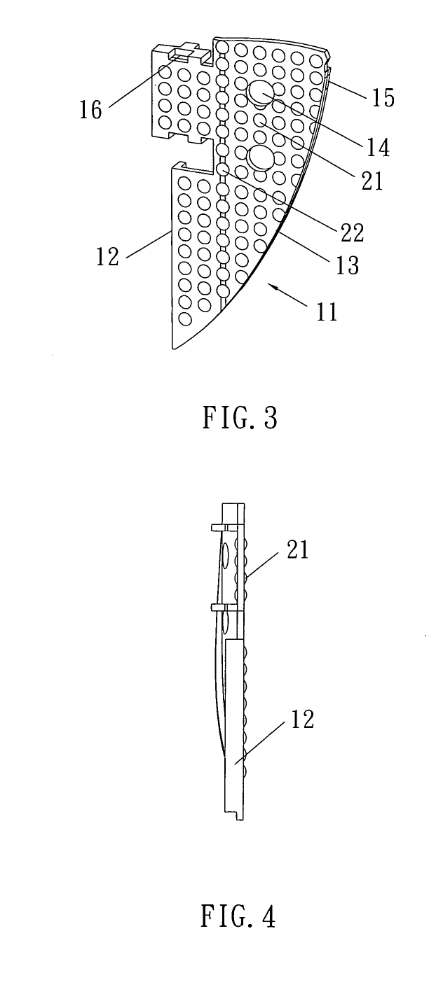

FIG. 3 is a schematic view showing a fin of the heat dissipating device according to another embodiment of the invention. Referring to FIG. 3, the heat dissipating fin 11 has an inner plate edge 12 and an outer plate edge 13. The inner plate edge 12 includes a connection member 16, and the outer plate edge 13 includes a curved surface corner 15. The heat dissipating fin 11 comprises a plurality of projections 21 and a plurality of depressions 22. The heat dissipating fins further comprises one hole or a plurality of holes 14 to increase the efficiency of a thermal convection and to enlarge a heat dissipating area. FIG. 4 is a side view illustrates the heat dissipating fin of the invention.

The heat dissipating fin 11 is rotated by an angle base on a direction of an air-flowing. The inner plate edges 12 of the heat dissipating fins 11 are respectively or simultaneously in contact with a heat source to dissipate heat. The heat source is a circular cylinder, an elliptical cylinder, a circular cone, a heat pipe, a plate-type heat pipe or a loop heat pipe having a good heat transfer property.

The heat dissipating fins 11 are made of different materials, such as aluminum, copper, any suitable thermal conductive metal material or an alloy thereof. The heat dissipating fins 11 have different thicknesses.

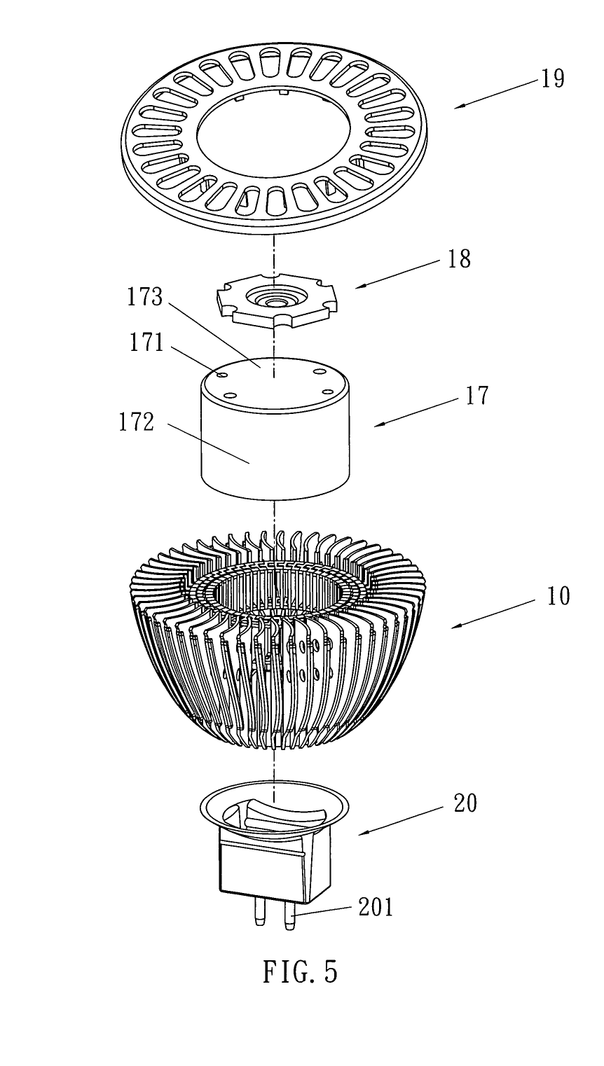

FIG. 5 illustrates an application embodiment of the heat dissipating device according to the invention. As shown in FIG. 5, the heat dissipating device is applied to a heat dissipating module of a LED lamp. A thermal conductive carrier 17 is disposed on a center portion of the heat dissipating device 10. The thermal conductive carrier 17 having a platform 173 is hollow. After the thermal conductive carrier 17 is placed in the heat dissipating device 10, the center portion of the heat dissipating device 10 is divided into an upper space and a lower space. A light-emitting diode (LED) substrate 18 having a ring portion 19 is disposed on the thermal conductive carrier 17. An electrically controlled carrier 20 for driving the LED is disposed on the lower space of the center portion of the heat dissipating device 10.

The platform 173 of the thermal conductive carrier 17 having a plurality of holes are being passed through by wires on the LED substrate 18. The wires are electrically connected to the electrically controlled carrier 20, wherein the wires are connected to the power supply by the pins 201. The thermal conductive carrier 17 is made of aluminum, copper, any suitable thermal conductive metal material or an alloy thereof.

In summary, the invention has overcome the drawbacks of the conventional structure and achieves the effects to be enhanced.

New characteristics and advantages of the invention covered by this document have been set forth in the foregoing description. It is to be expressly understood, however, that the drawings are for the purpose of illustration only and are not intended as a definition of the limits of the invention. Changes in methods, shapes, structures or devices may be made in details without exceeding the scope of the invention by those who are skilled in the art. The scope of the invention is, of course, defined in the language in which the appended claims are expressed.

What is claimed is:

1. A heat dissipating device, comprising:
a plurality of heat dissipating fins are sequentially connected together to form a continuous and cascaded heat dissipating fin set, wherein the heat dissipating fin set having an outward radial shape, the heat dissipating fins comprise at least one local arc shape, surfaces of the heat dissipating fins having projections and depressions to enlarge a heat dissipating area, and edges of the fins are formed with curved surface corners to prevent an operator from being cut and hurt.

2. The heat dissipating device according to claim 1, wherein each of the heat dissipating fins further comprises one hole or a plurality of holes to improve the efficiency of a thermal convection.

3. The heat dissipating device according to claim 1, wherein each of the heat dissipating fins is rotated by an angle based on a direction of an air-flowing.

4. The heat dissipating device according to claim 1, wherein inner plate edges of the heat dissipating fins are respectively or simultaneously in contact with a heat source to dissipate heat.

5. The heat dissipating device according to claim 4, wherein the heat source is a circular cylinder, an elliptical cylinder, a circular cone, a heat pipe, a plate-type heat pipe or a loop heat pipe having a good heat transfer property.

6. The heat dissipating device according to claim 1, wherein the heat dissipating fins are made of different materials.

7. The heat dissipating device according to claim 6, wherein the material of the heat dissipating fin is aluminum, copper, a thermal conductive metal material or an alloy thereof.

8. The heat dissipating device according to claim 1, wherein the heat dissipating fins have different thicknesses.

9. The heat dissipating device according to claim 1, further comprising a fan to improve the efficiency of heat dissipation.

10. A heat dissipating device used in a heat dissipating module of a projection light source, comprising:
a plurality of heat dissipating fins are sequentially connected together to form a continuous and cascaded heat dissipating fin set, wherein the heat dissipating fin set having an outward radial shape, the heat dissipating fins comprise at least local arc shapes, surfaces of the heat dissipating fins having projections and depressions to enlarge a heat dissipating area, and edges of the fins are formed with curved surface corners to prevent an operator from being cut and hurt, a thermal conductive carrier is placed at a center portion of the heat dissipating device, the thermal conductive carrier having a platform is hollow, the center portion of the heat dissipating device is divided into two spaces, an upper space and a lower space, after the thermal conductive carrier is placed in the heat dissipating device, a light-emitting diode (LED) substrate having a ring portion is disposed on the thermal conductive carrier, and an electrically controlled carrier for driving the LED is disposed on the lower space of the center portion of the heat dissipating device.

11. The heat dissipating device according to claim 10, wherein the platform of the thermal conductive carrier having a plurality of holes is being passed through by wires on the LED substrate penetrate.

12. The heat dissipating device according to claim 10, wherein the thermal conductive carrier is made of aluminum, copper, a thermal conductive metal material or an alloy thereof.
